(19) United States
(12) Patent Application Publication
(10) Pub. No.: US 2026/0173326 A1
(43) Pub. Date: Jun. 18, 2026

(54) Switch having vertically oriented host and mezzanine cards

(71) Applicant: Eridu Corporation, Saratoga, CA (US)

(72) Inventors: Christopher Robert Cole, Redwood City, CA (US); Drew D. Perkins, Saratoga, CA (US)

(21) Appl. No.: 18/977,929

(22) Filed: Dec. 12, 2024

(51) Int. Cl. H05K 7/20; H01R 12/73; H05K 7/14

(52) U.S. Cl. CPC H05K 7/20781; H01R 12/737; H05K 7/1492; H05K 7/20836; H05K 2201/10189

(57) ABSTRACT

An apparatus is provided that comprises a housing with vertically oriented first cards, referred to herein as mezzanine or daughter cards, adjacent to the front side of the housing. These mezzanine cards are configured to connect to interface modules capable of receiving and transmitting optical signals or electrical signals. A second card, referred to herein as a host or line card, also vertically extends within the housing and includes a processor package with a processor, such as a switch ASIC, for processing or switching data associated with the optical signals. The system employs connectors that couple the mezzanine cards to the line card, and includes a plurality of heat transfer elements, such as cold plates or air-cooled heat sinks, to facilitate thermal management with the interface modules.

### BACKGROUND

The document describes switching systems configured to receive optical and electrical modules.

### SUMMARY

An apparatus is provided that comprises a housing with vertically oriented first cards, referred to herein as mezzanine or daughter cards, adjacent to the front side of the housing. These mezzanine cards are configured to connect to interface modules capable of receiving and transmitting optical signals or electrical signals. A second card, referred to herein as a host or line card, also vertically extends within the housing and includes a processor package with a processor, such as a switch ASIC, for processing or switching data associated with the optical signals. The system employs connectors that couple the mezzanine cards to the line card, and includes a plurality of heat transfer elements, such as cold plates or air-cooled heat sinks, to facilitate thermal management of the interface modules.

### BRIEF DESCRIPTION OF THE DRAWINGS

FIG. 1 depicts an exemplary system configured for data processing and optical and/or electrical communication within a data center environment, accordance with some embodiments of the present disclosure;

FIG. 2A shows a simplified perspective view of a switch consistent with an aspect of the present disclosure;

FIG. 2B shows a high level perspective view of internal components of the switch shown in FIG. 2A consistent with a further aspect of the present disclosure;

FIG. 3 shows a front view of a switch consistent with an additional aspect of the present disclosure;

FIG. 4 shows a cross-sectional view of internal components of the switch shown in FIG. 3;

FIG. 5 shows a front view of a switch consistent with a further aspect of the present disclosure;

FIG. 6 shows a cross-sectional view of internal components of the switch shown in FIG. 5;

FIG. 7 shows a front view of a switch consistent with an additional aspect of the present disclosure; and

FIG. 8 shows a cross-sectional view of internal components of the switch shown in FIG. 7.

### DETAILED DESCRIPTION

The following detailed description of example implementations refers to the accompanying drawings. The same reference numbers in different drawings may identify the same or similar elements.

Communication networks, such as those provided in data centers often include switches for directing data between various processing units, such as CPUs, GPUs, and further interconnected switches. These switches often include optical or electrical transceiver modules and electrical processing components, such as a switch application specific integrated circuit (ASIC) provided in a chassis. As increasing numbers of processing units are provided in a data center, for example, higher capacity switches may be required that can accommodate a large number of transceiver modules. However, such switches require greater connectivity, higher component density, and thermal management. Moreover, manufacturing or assembling high capacity switches may be difficult in light of such requirements.

In light of the foregoing, some implementations described herein provide an apparatus designed for optimized physical layout and connectivity within data center switches. For example, the apparatus comprises a housing with vertically oriented first cards, referred to herein as mezzanine or daughter cards, adjacent to the front side of the housing. These mezzanine cards are configured to connect to interface modules capable of receiving and transmitting optical signals or electrical signals. A second card, referred to herein as a host or line card, also vertically extends within the housing and includes a processor package with a processor, such as a switch ASIC, for processing or switching data associated with the optical signals. The system employs connectors that couple the mezzanine cards to the line card, and includes a plurality of heat transfer elements, such as cold plates or air-cooled heat sinks, to facilitate thermal management with the interface modules. In some aspects, the interface modules can process electrical signals, and the processor can encompass various types of data processors, such as ASICs, particularly a switch ASIC, or other processing units like GPUs or NPUs, consistent with the requirements of high-performance computing (HPC) and data switching tasks, for example. Other integrated circuits may be provided on the vertical line card 212, for example.

Additionally, the mezzanine cards are configured to provide the flexibility for housing integrated circuits, and the apparatus supports a variety of interconnections, such as low-profile and tall connectors, and the layout permits cabled connections that are unobstructed and easily accessible, which is beneficial for manufacturing and assembly processes. The architectural design enables a configurable gap that delineates an area on the host card for the processor package, thus avoiding any overlap with the mezzanine cards that could restrict cooling efficiency and maintenance activities.

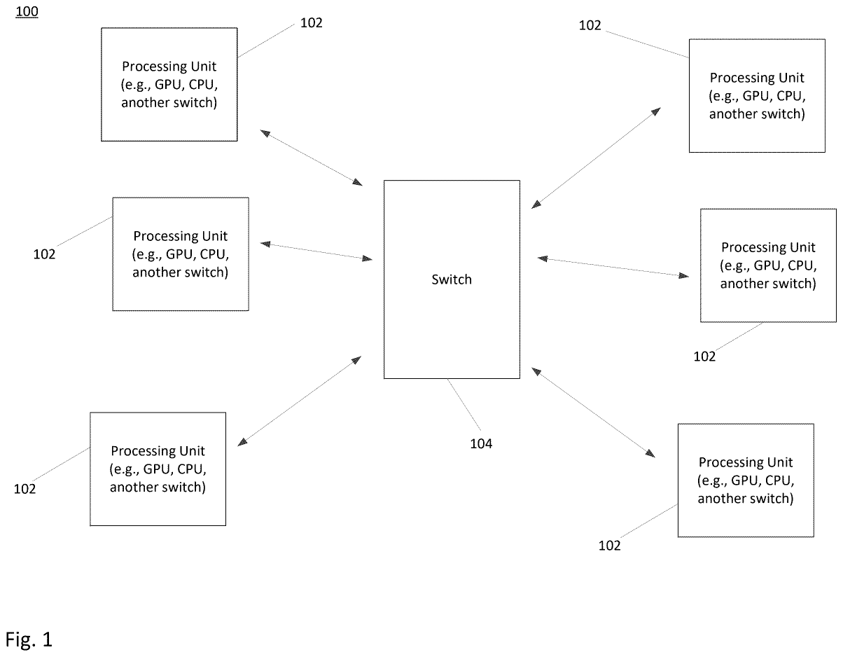

FIG. 1 depicts a system 100 configured for data processing and optical and/or electrical communication within a data center environment, for example. The system 100 comprises a plurality of processing units 102 interconnected to a switch 104. Each processing unit 102 may include a graphics processing unit (GPU), a central processing unit (CPU), or alternatively operate as another switch. In the illustrated architecture, switch 104 is operable to receive data transmissions from one or more of the processing units 102 and to direct this data accordingly to one or more of the other processing units 102.

As indicated above, FIG. 1 is provided as an example. Other examples may differ from what is described with regard to FIG. 1. The number and arrangement of components shown in FIG. 1 are provided as an example. In practice, there may be additional components, fewer components, different components, or differently arranged components than those shown in FIG. 1.

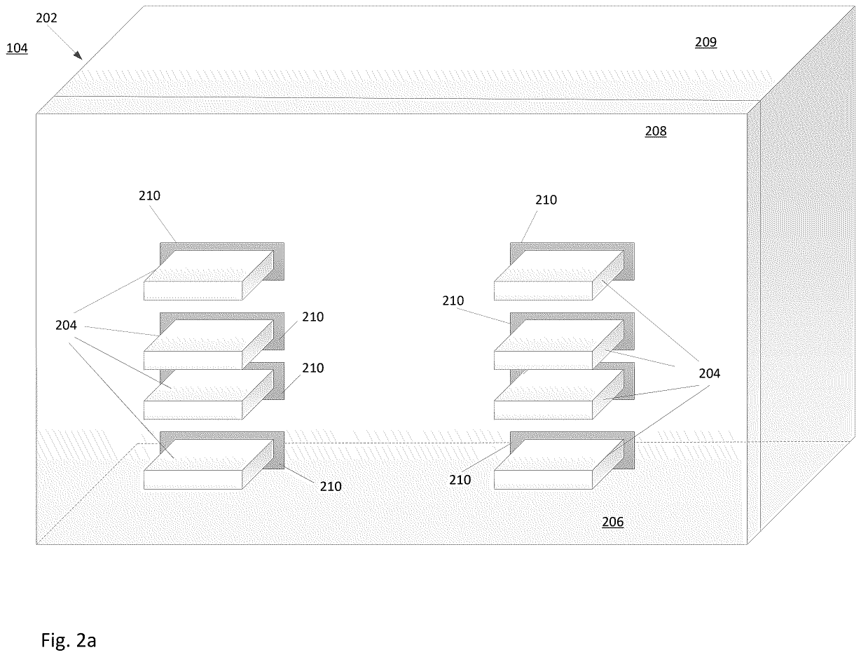

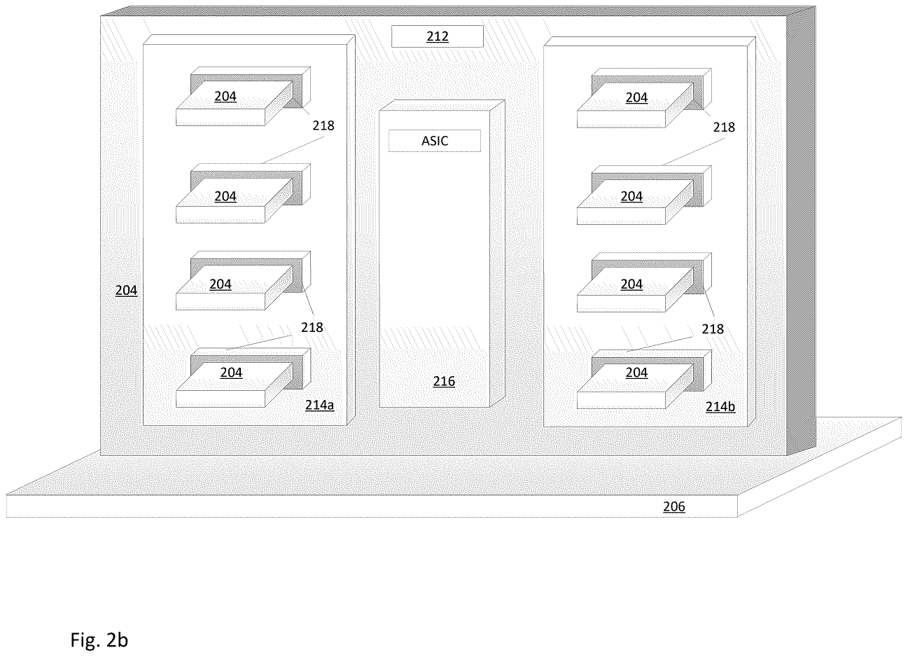

FIG. 2A shows switch 104 in greater detail. As shown in FIG. 2A, switch 104 includes a housing or chassis 202 that comprises a bottom 206 and a top 209. The housing 202 additionally features a front panel 208 which includes a plurality of module slots or ports 210.

Each module slot 210 is configured to receive a corresponding optical or electrical module or interface module 204, which in one example is a transceiver module. These modules or interface modules 204 facilitate communication between switch 104 and processing units 102 (not shown in this figure). Modules 204 supporting optical communication are operable to convert input optical signals into input electrical signals for processing or switching, and by converting processed or switched electrical signals into output optical signals. Each module may be a pluggable module, such as a module complying with an OSFP standard or OSFP module.

Put another way, modules 204 may be embodied as transceiver modules, capable of both outputting optical signals carrying data to at least one of the processing units 102 and receiving optical signals carrying data from at least one of the processing units 102. In this particular embodiment, the modules 204 are shown as being provided in module slots 210 of the front panel 208. In a further example, modules 204 may be transceiver modules that output or transmit first electrical signals as well as receive second electrical signals.

The housing 202 is designed with structural features to support the integration of modules 204, ensuring their alignment and secure attachment within the module slots 210 and providing protection for internal components. Although not specifically illustrated in FIG. 2A, the housing 202 may contain additional components, such as data processors and circuits, which interact with the modules 204 to perform necessary communication and signal conversion functions.

As indicated above, FIG. 2A is provided as an example. Other examples may differ from what is described with regard to FIG. 2A.

FIG. 2B shows a simplified perspective view of components provided within switch 104. Namely, FIG. 2B shows a vertical host card 212, also referred to as a vertical line card, designed to operate within the switch 104.

The vertical host card 212 supports a processor, such as an application-specific integrated circuit (ASIC) 216, mounted on the card and facing the front panel 208 of the chassis 202. The ASIC 216 may provide specialized processing operations, such as switching, required for routing or directing data through switch 104. While FIG. 2B illustrates the ASIC 216 positioned on the side of the vertical host card 212 that faces the front panel 208, it is contemplated that the ASIC 216 could alternatively be positioned on the reverse side, facing away from the front panel 208 towards the back of the chassis 202. Other integrated circuits sim

In this arrangement, two vertical mezzanine cards are shown, specifically the first vertical mezzanine card 214a and the second vertical mezzanine card 214b. One or both cards, as well as mezzanine cards disclosed below may include integrated circuits provided thereon. In this example, these mezzanine cards or daughter cards as well as the vertical host or line card 212 extended perpendicular to the housing bottom 206. Put another way, the mezzanine cards 214 and line card 212 extend in a direction from the bottom 206 of the housing to the top 209 of the housing Each mezzanine card 214 is equipped with connectors 218 that facilitate the attachment of optical or electrical modules 204. Additional connectors described in greater detail below facilitate connection to vertical host card 212.

The connectors 218 on the vertical mezzanine cards 214 are designed to accommodate modules 204, which may be optical transceiver modules or modules carrying data signals in electrical form. In one example, each module 204 plugs directly into a corresponding connector 218 on the vertical mezzanine cards 214a and 214b, establishing a signal pathway to the ASIC 216 through conductive connections such as electrical traces.

The bottom of the housing 206 provides a structural base for securely positioning the vertical host card 212 and the associated components within the switch's enclosure. The arrangement of the vertical host card 212 with its mounted ASIC 216, along with the vertical mezzanine cards 214a and 214b and their respective connectors 218, represents an example configuration that facilitates effective communication between the modules 204 and the processing unit within the switch via the ASIC 216.

Alternate configurations with varying numbers and arrangements of mezzanine cards, host cards, connectors, and modules are also considered to fall within the scope of the present disclosure.

As indicated above, FIG. 2B is provided as an example. Other examples may differ from what is described with regard to FIG. 2B. The number and arrangement of components shown in FIG. 2B are provided as an example. In practice, there may be additional components, fewer components, different components, or differently arranged components than those shown in FIG. 2B.

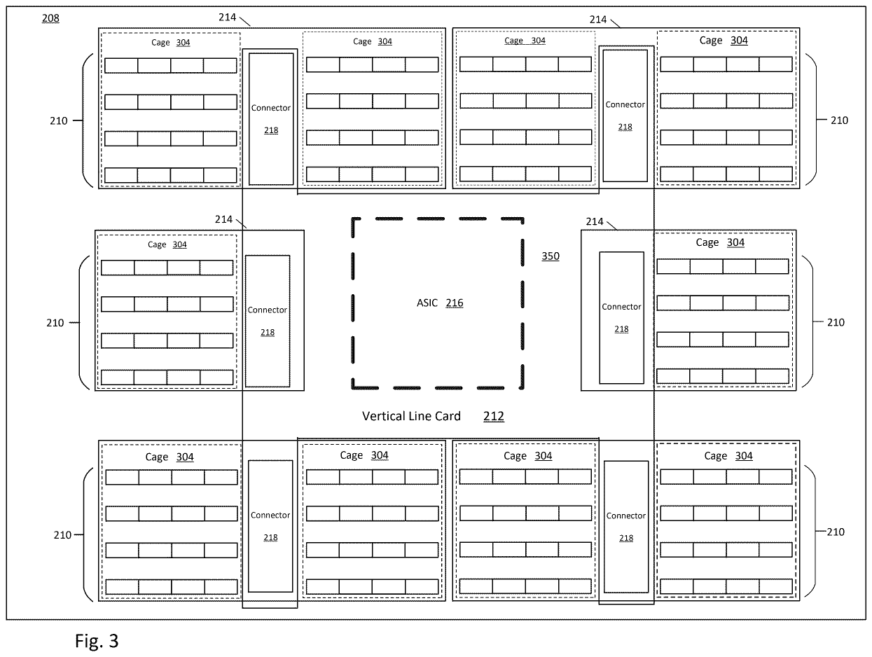

FIG. 3 shows a front view of a switch consistent with a further aspect of the present disclosure. As shown in FIG. 3, the switch includes vertical mezzanine cards 214, which are arranged to define a gap or space 350 that defines a region on the vertical line card 212 including the switch ASIC 216. The vertical mezzanine cards 214 connect to a plurality of optical or electrical modules 204 and incorporate at least one connector 218 for interfacing with the vertical line card 212. In one example, the front panel 208 of the switch include slots 210 for receiving each module 204. Further, one or more additional integrated circuits, such as IC 390, may be provided on card 212.

In the current implementation, the vertical mezzanine card 214 is configured to maintain the optical or electrical modules 204 in an organized framework. These modules 204 may be diverse in nature, for example, including transmitters, receivers, transceivers, or other signal processing modules that may engage in optical to electrical signal conversions and vice versa.

As described in greater detail below, two-piece connectors may be provided to electrically connect the mezzanine card 214 to hose card 212.

In one example, the configuration of vertical mezzanine cards 214 is such that peripheral portions of these cards do not overlap with the switch ASIC 216 on the vertical line card 212 to prevent interference. Accordingly, as shown in FIG. 3, gap 350 is shown over ASIC 216. Additionally, the arrangement of the mezzanine cards 214 in FIG. 3 shows cages 304, which serve to protect and organize the optical or electrical modules 204. These cages 304 are typically constructed to provide a stable structure for module insertion and retention, as well as aiding in thermal management and electromagnetic interference (EMI) shielding. The perimeter of

More specifically, FIG. 3 shows another example of the front panel 208 of chassis 202 with 160 optical module slots 210, which are configured to accommodate and receive an optical transceiver module, such as a module compliant with an OSFP standard of OSFP module. The modules or interface modules may be pluggable, such as into a connector as described below. In a further example, an 800 Gb/s module 204 supports a total interconnect bandwidth of 128 Tb/s. Other numbers of module slots 210 and module bandwidths results in different interconnect bandwidths. The optical modules 204 are grouped in 4×4 two-dimensional array of cages 304, in the example shown in FIG. 3. Other cage groupings and other cage array sizes, such as 8×4 two-dimensional array are contemplated herein. Moreover, the example shown in FIG. 3 includes six vertical mezzanine cards (also referred to herein as “VMCs”) 214 on which the optical modules 204 are mounted in a similar manner to how optical modules may be mounted on a vertical line card (also referred to herein as “VLC”), although further consistent with the present disclosure, more or fewer vertical mezzanine cards may be provided. In the example shown in FIG. 3, only ASIC 216 is provided on vertical line card (VLC) 212 and other support circuitry are located, but no optical modules.

In FIG. 3, for example, the size of an area of the vertical line card 212 is greater than an area of each of the mezzanine line card 214.

As indicated above, FIG. 3 is provided as an example. Other examples may differ from what is described with regard to FIG. 3. The number and arrangement of components shown in FIG. 3 are provided as an example. In practice, there may be additional components, fewer components, different components, or differently arranged components than those shown in FIG. 3.

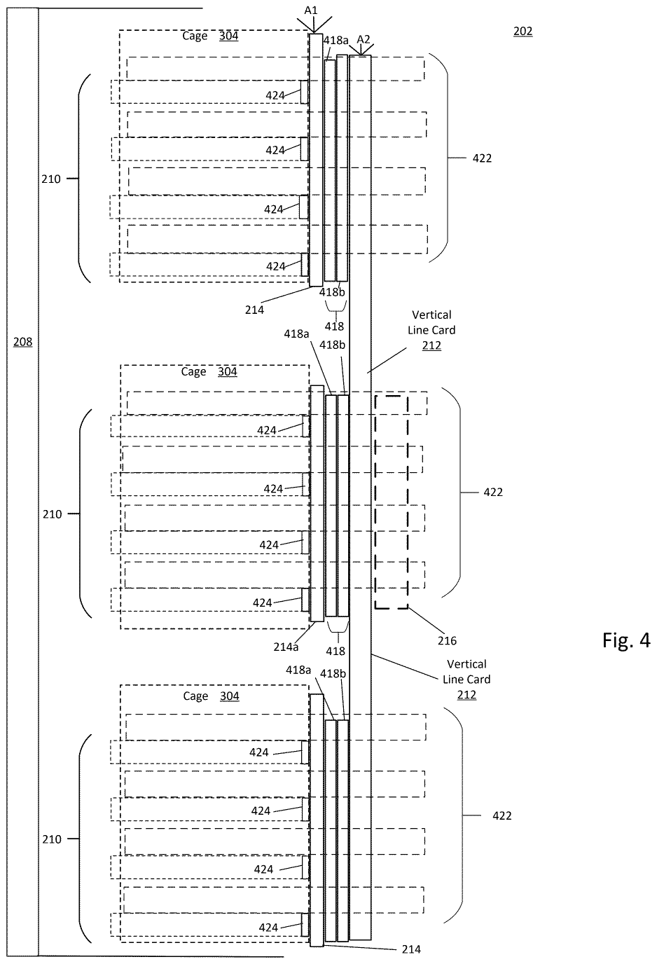

FIG. 4 shows a cross-sectional view of internal components of switch 104 shown in FIG. 3. In particular, the example shown in FIG. 4 includes an arrangement of vertical mezzanine cards (VMCs) 214 in proximity to a vertical line card (VLC) 212 for optimizing signal integrity and thermal management in switch 104.

As noted above, vertical mezzanine cards 214 each house a plurality of optical or electrical modules contained within the module slots or ports 210. These modules, though not explicitly labeled, are understood to be housed within each VMC 214.

As further shown in FIG. 4, vertical mezzanine cards 214 are equipped with at least one connector 418 for providing an electrical interface with the vertical line card 212. In one example, connector 418 may be a two-piece low profile connector including a first part 418a and a second part 418b. Moreover, heat transfer elements 422, which may include one of a cold plate, an air-cooled heat sink, or a liquid cooled cold plate are provided to remove heat from modules 204 when such modules are provided in module cages 304. In addition receptacle connector 424 may be provided to receive and provide an electrical connection to each module when inserted in to a slot 210.

In FIG. 4, vertical mezzanine cards (VMCs) 214 and vertical line card VLC 212 are located relatively close to one another so that a low-profile two-piece connector 418 connects these two cards. As a result, a relatively high signal integrity may be obtained. However, in order to provide the VMCs 214 in close proximity to VLC 212, preferably no VMC or portion of a VMC is located in front of the ASIC on VLC 212, to thereby prevent interference. In FIGS. 3 and 4, each VMC 214 is shown mounting one connector 218. However, the connection between these cards may be realized with a multiple smaller size connectors also referred to as a connector field. As noted above, modules 204 may be cooled by heat transfer elements, such as heat sinks or cold plates. If heat sinks are provided, an air flow is preferably directed over the heat sinks. As a result, heat generated by modules 204, when such modules are provided in cages 304, and absorbed by the heat sinks is dissipated by the air flow, thereby cooling the heat sinks. Preferably, the heat sinks are mounted to the top of and are thus in contact with the modules 204, and the air flow is through holes in the VMCs, similar to through holes which may be provided in the VLCs. The modules can also be cooled by a cold plate, which can also extend through holes in the VMCs, with heat extracted behind them by way of a liquid coolant, for example.

As noted above, housing 202 includes, among other things, vertical mezzanine cards or daughter cards 214 and a vertical host or line card 212. In one example, each of the plurality of vertical mezzanine cards 214 is oriented at a first angle A1 relative to the front panel 208, the first angle is in a range from −60° to 60°. In addition, vertical line card 212 may be oriented at a second angle A2 in a range from −60° to 60° relative to front panel 208, as also shown in FIG. 4. In a further example, both first angle A1 and second angle A2 are both 0°, such that each cards 214 and card 212 are parallel to front panel 208. Angles A1 and A2 may be the same or different, consistent with the present disclosure. Line card and mezzanine cards discussed below may also be oriented within a range of −60° to 60° relative to front panel 208 in a manner similar to that discussed above in connection with FIG. 4.

As indicated above, FIG. 4 is provided as an example. Other examples may differ from what is described with regard to FIG. 4, such as in the number of components.

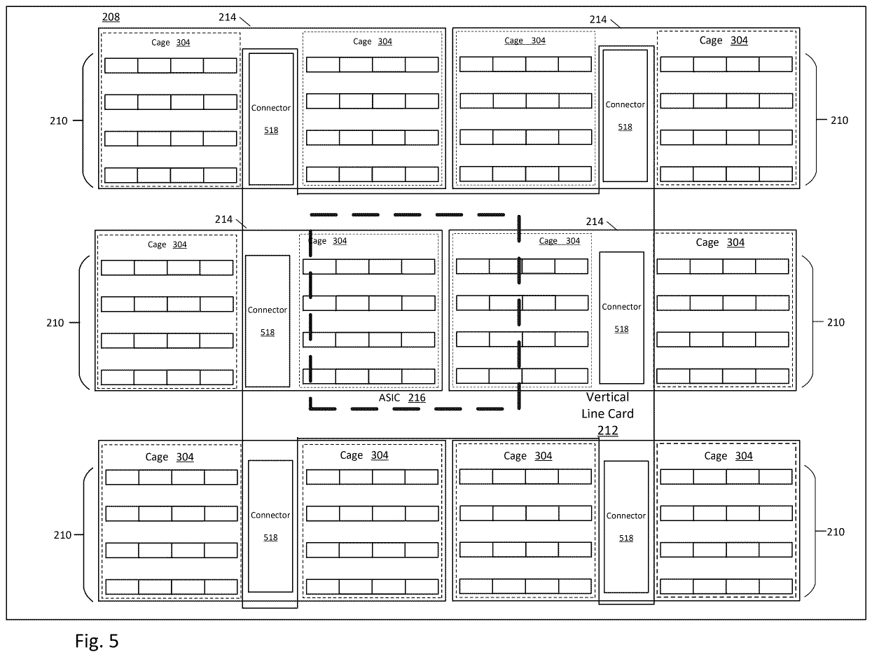

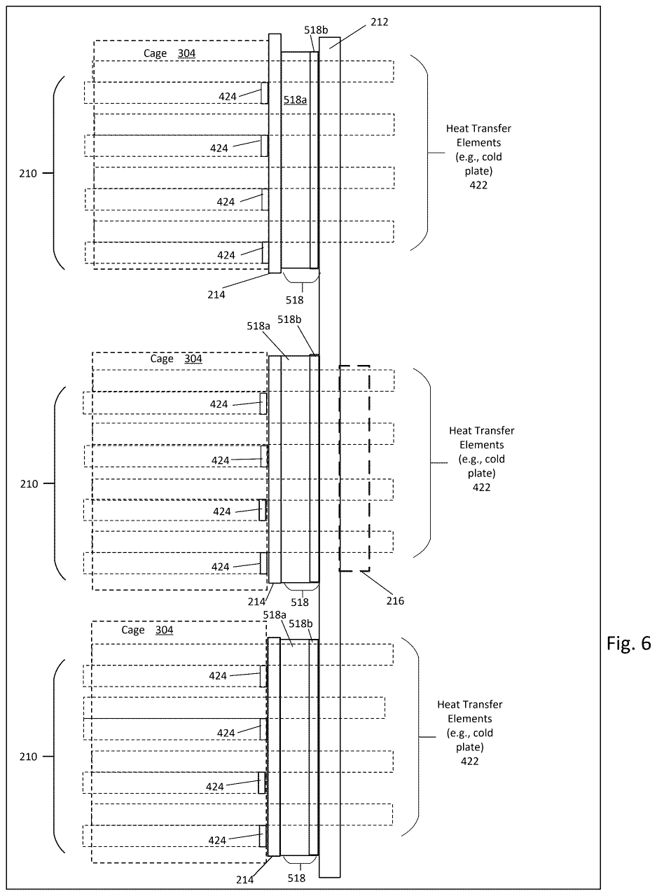

FIG. 5 shows a front view of a switch consistent with a further aspect of the present disclosure. Namely, the example shown in FIG. 5 is similar to that shown in FIG. 4. In FIG. 5, however, connector 518 are provided, as discussed in greater detail with respect to FIG. 6. In addition, as shown in FIG. 5, two of the vertical mezzanine cards 214 are shown overlapping ASIC 216.

FIG. 6 shows a cross-sectional view of components within the switch shown in FIG. 5. The components are similar to those shown in FIG. 5. For example, heat transfer elements 422 and receptacle connectors 424 are shown in both FIG. 5 and FIG. 6.

FIG. 6, however, shows a vertical mezzanine card 214a overlapping ASIC 216, as noted above. In addition, tall two-piece connectors are show having a first piece 518a and a second piece 518b that provide an electrical connection between mezzanine cards 214 and vertical line card 212.

Thus, taken together, FIGS. 5 and 6 show an example in which VMCs 214 overlap the ASIC 216 and support 192 optical module slots 210. This is enabled by a two-piece tall connector 518 as shown in FIG. 6. This enables the overlapping VMCs 214 to clear power and other circuitry located behind the ASIC 216 on the VLC 412. The space also allows air flow to go around the VLC or leaves space for accommodating a heat exchanger with module cold plates.

As indicated above, FIGS. 5 and 6 are provided as examples. Other examples may differ from what is described with regard to FIGS. 5 and 6. In addition, the number and arrangement of components shown in FIGS. 5 and 6 are provided as an example. In practice, there may be additional components, fewer components, different components, or differently arranged components than those shown in FIGS. 5 and 6.

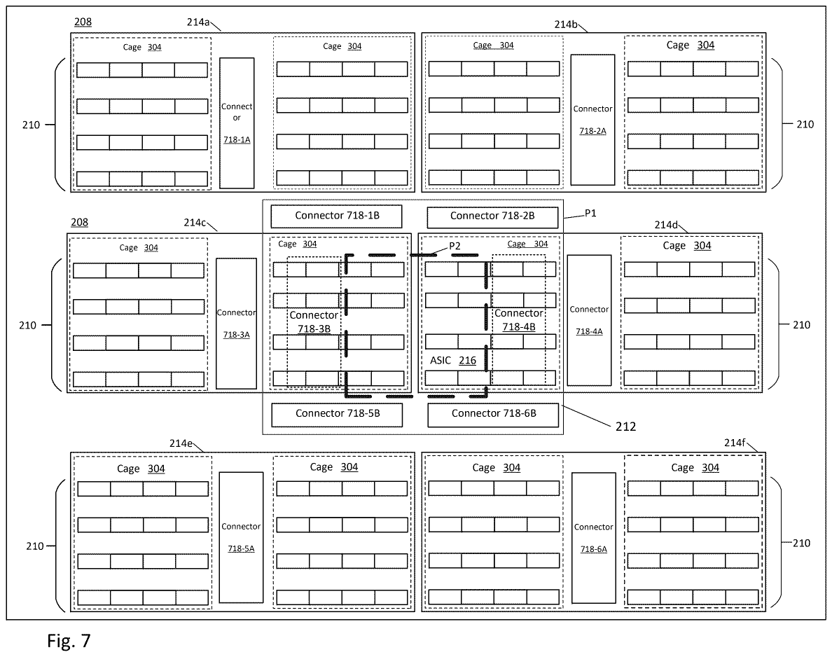

FIG. 7 shows another example of a front view of a switch 104 consistent with a further aspect of the present disclosure. Here, vertical line card 212 is smaller than that shown in FIGS. 3 and 5 and only overlaps with two vertical mezzanine cards 214c and 214d instead of six vertical mezzanine cards, as in FIGS. 3 and 5. Moreover, perimeter P2 of ASIC 216 on VLC 212 and a perimeter P1 of the VLC 212 are shown in FIG. 7 as overlap only selected ones of VMC cards 214, namely, VMCs 214c and 214d. In addition, in FIGS. 3 and 5 each VMC is shown as having an area and size that is less than that of the VLC. In FIG. 7, however, the VLC has a smaller area and a smaller size compared to each VMC shown therein.

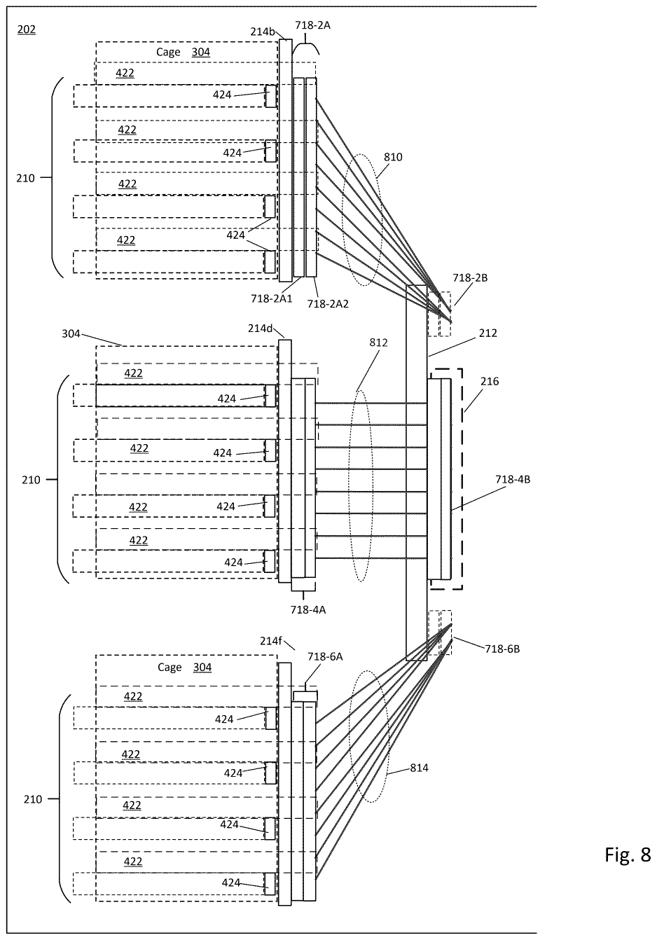

Further additional two piece connectors (718-1A to 718-6A and 718-1B to 718-6B) are provided and cables are used to connect the mezzanine and line or host cards, as discussed in greater detail below with reference to FIG. 8.

As shown in FIG. 8, module slots 210 and receptacle connectors are provided in a manner similar to that described above. In addition, low profile connectors 718-2A, 718-4A, and 718-6A are provided to connect to vertical mezzanine cards 214b, 214d, and 214f, respectively. Such low profile connectors are preferably two-piece connections and have a first piece, such as connector piece 718-2A1 and a second piece, such as connector piece 718-2A2. Moreover, connectors 718-1B to 718-6B are provided on vertical line card 212. In FIG. 8, however, three such connectors, which may be two-piece connectors, are provided on vertical line card 212. These three connectors are shown as connector 718-2B, 718-4B, and 718-6B. Cables or cable bundles 810 are shown providing an electrical connections between connector 718-2A on MLC 214b and 718-2B on VLC 212; cables or cable bundles are shown providing electrical connections between connector 718-4A on VMC 214d and connector 718-4B on VLC 212; and cables or cable bundles are shown providing electrical connections between connector 718-6A on VMC 214f and connector 718-6B on VLC 212.

In one example, FIG. 7 shows VMCs 214 overlapping the ASIC 216, also supporting 192 optical module slots 210. FIG. 8 shows the separation between VMC 214b, 214d, and 214f, for example, and VLC 212 greater than in FIG. 7. In particular, FIG. 8 shows an example that enables use of cables, e.g., cables 810, 812, and 814 to connect such VMC cards to VLC 212. The cables have connectors, i.e., are “connectorized” at each end. The connectors on the VLC 212 are mounted on the same side as the ASIC 216 to enable ease of installation. The connectors and the VMCs 214 are also facing backwards, away from the front panel of the chassis, and do not overlap with the VLC 212, enabling ease of installation. This configuration supports a large number of cables which can be bundled together for easier manufacturability. Each VMC 214 is shown with one connector, but it is understood that multiple connectors, e.g., a connector field including many smaller connectors, may be provided. In one example, if the optical module 204 provided in the slots 210 is an OSFP module with eight high-speed differential transmit and receive pairs, each connector, or connector field, therefore, requires 128 high-speed differential transmit and receive pairs. Here, the total number of transmit and receive pairs is 1536. Different number of modules or different module types results in a different number of transmit and receive pairs.

As indicated above, FIGS. 7 and 8 are provided as examples. Other examples may differ from what is described with regard to FIGS. 7 and 8. In addition, the number and arrangement of components shown in FIGS. 7 and 8 are provided as an example. In practice, there may be additional components, fewer components, different components, or differently arranged components than those shown in FIGS. 7 and 8.

The foregoing disclosure provides illustration and description, but is not intended to be exhaustive or to limit the implementations to the precise forms disclosed. Modifications may be made in light of the above disclosure or may be acquired from practice of the implementations.

Although particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

What is claimed is:

1. An apparatus, comprising:
a housing having a front panel, a top and a bottom;
a plurality of first cards provided vertically in the housing adjacent the front side of the housing, such that each of the plurality of first cards is oriented at a first angle relative to the front panel, the first angle is in a range from −60° to 60°;
a plurality of module cages, each of which being attached to a respective one of the plurality of first cards;
a plurality of first connectors being electrically connected to the plurality of first cards;
a second card provided vertically in the housing, such that the second card is oriented at a second angle relative to the front panel, the second angle is in a range of −60° to 60°, the second card including a processor;
a plurality of second connectors being operable to electrically connect the plurality of first cards to the second card; and
a plurality of heat transfer elements being operable to transfer heat away from a plurality of interface modules when each of the plurality of interface modules is provided in a respective one of the plurality of module cages,
wherein selected ones of the plurality of module cages overlap with the second card.

2. An apparatus in accordance with claim 1, wherein each of the second connectors includes a tall profile connector.

3. An apparatus in accordance with claim 1, wherein the plurality of interface modules being operable to transmit a first plurality of optical signals and receive a second plurality of optical signals, wherein the plurality of module cages being operable to accommodate a plurality of interface modules, such that each of the plurality of first connectors electrically connects a respective one of the plurality of interface modules to an associated one of the plurality of first cards.

4. An apparatus in accordance with claim 1, wherein each of the plurality of second connectors includes:
a cable;
a first connector operatively connected to a first end of the cable and an associated one of the plurality of first cards; and
a second connector operatively connected to a second end of the cable and the second card.

5. An apparatus in accordance with claim 1, wherein the plurality of second connections include cables, the cables having first ends being attached to the plurality of first cards by first cable connectors and second ends connected to the second card by second cable connectors.

6. An apparatus in accordance with claim 5, wherein the first cable connectors are non-overlapping with the second card.

7. An apparatus in accordance with claim 5, wherein each of the second cable connectors is non-overlapping with each of the plurality of first cards.

8. An apparatus in accordance with claim 5, wherein each of the first cable connectors is non-overlapping with the second card and each of the second cable connectors is non-overlapping with each of the plurality of first cards.

9. An apparatus in accordance with claim 1, wherein the second card includes an integrated circuit.

10. An apparatus in accordance with claim 1, wherein each of the plurality of heat transfer elements includes a cold plate.

11. An apparatus in accordance with claim 10, wherein the cold plate is configured to be liquid-cooled.

12. An apparatus in accordance with claim 1, wherein each of the plurality of heat transfer elements includes an air-cooled heat sink.

13. An apparatus in accordance with claim 1, wherein the plurality of interface modules being operable to transmit a first plurality of electrical signals and receive a second plurality of electrical signals, wherein the plurality of module cages being operable to accommodate a plurality of interface modules, such that each of the plurality of first connectors electrically connects a respective one of the plurality of interface modules to an associated one of the plurality of first cards.

14. An apparatus in accordance with claim 1, wherein the processor includes a switch.

15. An apparatus in accordance with claim 1, wherein the processor includes a network processing unit (NPU).

16. An apparatus in accordance with claim 1, wherein the processor includes a graphics processing unit (GPU).

17. An apparatus in accordance with claim 1, wherein the processor includes an application specific integrated circuit (ASIC).

18. An apparatus in accordance with claim 1, wherein the ASIC is a switch ASIC.

19. An apparatus in accordance with claim 18, wherein the switch ASIC includes a first integrated circuit, the second card further including a plurality of second integrated circuits.

20. An apparatus in accordance with claim 3, wherein the front panel of the housing includes a plurality of module cages arranged in a two-dimensional array, each of the plurality of module cages being configured to accommodate a respective one of the plurality of interface modules.

21. An apparatus in accordance with claim 13, wherein the front panel of the housing includes a plurality of module cages arranged in a two-dimensional array, each of the plurality of module cages being configured to accommodate a respective one of the plurality of interface modules.

22. An apparatus in accordance with claim 3, wherein each of the plurality of interface modules is a pluggable module.

23. An apparatus in accordance with claim 3, wherein each of the plurality of interface modules is compliant with an OSFP standard.
